(19) United States
(12) Patent Application Publication
(10) Pub. No.: US 2020/0049752 A1
(43) Pub. Date: Feb. 13, 2020

(54) INSPECTION DEVICE FOR COLLECTOR HEAD AND INSPECTION METHOD OF COLLECTOR HEAD

(71) Applicants: Central Japan Railway Company, Aichi (JP); Koshin Seikosho, LTD., Saitama (JP)

(72) Inventors: Yuichi Ahiko, Aichi (JP); Kotaro Nakamura, Aichi (JP); Kenichi Kitazawa, Saitama (JP); Hiroaki Shintani, Saitama (JP)

(21) Appl. No.: 16/534,305

(22) Filed: Aug. 7, 2019

(30) Foreign Application Priority Data
Aug. 8, 2018 (JP) 2018149406

(51) Int. Cl. G01R 31/00

(52) U.S. Cl. CPC G01R 31/008

(57) ABSTRACT

Provided is an inspection device for contact strip that enables proper quality control of a collector head using a split-type contact strip. Disclosed is an inspection device for a collector head having an overhead contact line contact assembly that includes a contact strip, including electrically-conductive strip pieces aligned in a series and in a longitudinal direction, and springs elastically supporting the contact strip. The inspection device for a collector head includes a measurer of rigidity of the overhead contact line contact assembly in a thickness direction of the contact strip at multiple points on an axis parallel to the juxtaposition direction of the strip pieces; and a determiner of an abnormality in the collector head by comparison of measurement data of rigidity distribution at the multiple points based on measurement results from the measurer with reference data of rigidity distribution prepared beforehand.

### CROSS-REFERENCE TO RELATED APPLICATIONS

The present application claims the benefit of Japanese Patent Application No. 2018-149406 filed on Aug. 8, 2018 with the Japan Patent Office, the entire disclosure of which is incorporated herein by reference.

### BACKGROUND

The present disclosure relates to an inspection device for a collector head and an inspection method of the collector head.

Railroad vehicles are equipped with current collectors to receive electric current from overhead contact lines. The current collector has a collector head including a contact strip to contact the overhead contact line. The contact strip extends in a longitudinal direction of a sleeper and is configured such that the contact strip keeps in contact with the overhead contact line even if a relative position of the overhead contact line shifts in the longitudinal direction of the sleeper with respect to the railroad vehicle.

High speed railroad vehicles use a split-type contact strip which is configured to deflect in an up-down direction by strip pieces aligned in the longitudinal direction of the sleeper to achieve an enhanced follow-up performance to the overhead contact line (see Japanese Unexamined Patent Application Publication No. 2012-80640).

### SUMMARY

In conventional quality control of a collector head using a split-type contact strip, sizes and positions of the strip pieces are inspected. However, even if the contact strip is apparently assembled as designed, a designed deflection performance sometimes cannot be achieved due to an internal defect. Therefore, only the aforementioned inspection is insufficient for managing the quality in terms of contact stability with overhead contact lines (namely, current collection performance).

In one aspect of the present disclosure, it is preferable to provide an inspection device for a split-type contact strip used in a collector head, which enables proper quality control of the collector head.

One embodiment of the present disclosure is an inspection device for a collector head having an overhead contact line contact assembly that includes a contact strip, including electrically-conductive strip pieces aligned in a series and in a longitudinal direction, and springs that elastically support the contact strip. The inspection device for a collector head comprises a measurer configured to measure rigidity of the overhead contact line contact assembly in a thickness direction of the contact strip at multiple points on an axis parallel to the juxtaposition direction of the strip pieces, and a determiner configured to determine whether an abnormality has occurred in the collector head by comparison of measurement data of rigidity distribution at the multiple points based on measurement results from the measurer with reference data of rigidity distribution prepared beforehand.

This determiner configuration enables determination of whether the collector head has a rigidity distribution required for improving the contact stability with the overhead contact line. In other words, a defect in the collector head can be determined from the viewpoint of current collection performance; thus, proper quality control of the collector head can be achieved.

In one embodiment of the present disclosure, the collector head may further comprise a deflection plate that is located between the strip pieces and the springs, and is deformable in a thickness direction of the deflection plate. The collector head having such a configuration comprising the deflection plate has an improved followability to the overhead contact line, and proper quality control of the collector head including the deflection plate as an inspection target can be achieved.

In one embodiment of the present disclosure, the measurer may comprise a displacement sensor configured to measure a displacement of the contact strip in its thickness direction and a load sensor configured to measure a load applied on the contact strip in its thickness direction. This configuration enables easy and secure measurement of the rigidity of the overhead contact line contact assembly at multiple points.

In one embodiment of the present disclosure, the determiner may determine an abnormality occurring portion in the collector head based on results of a comparison between measurement data and reference data. This configuration enables easy identification of a cause of defect in the collector head.

Another aspect of the present disclosure provides an inspection method of a collector head having an overhead contact line contact assembly that includes a contact strip, including electrically-conductive strip pieces aligned in a series and in a longitudinal direction, and springs elastically supporting the contact strip. The inspection method of the collector head comprises processes of measuring rigidity of the overhead contact line contact assembly in a thickness direction at multiple points on an axis parallel to the juxtaposition direction of the strip pieces; and determining whether an abnormality has occurred in the collector head by comparison of measurement data of rigidity distribution at the multiple points based on measurement results obtained in the measuring process with reference data of rigidity distribution prepared beforehand.

This configuration enables determination on whether the collector head has a rigidity distribution required for an improved contact stability with the overhead contact line. In other words, a defect in the collector head can be determined from the viewpoint of current collection performance; thus proper quality control of the collector head can be achieved.

### BRIEF DESCRIPTION OF THE DRAWINGS

Some embodiments of the present disclosure will be described hereinafter by way of example with reference to the accompanying drawings, in which:

FIG. 1 is a schematic diagram of a current collector of a railroad vehicle;

FIG. 2A is a schematic sectional view of a collector head in the current collector of FIG. 1;

FIG. 2B is a schematic sectional view of the collector head in another condition than that in FIG. 2A;

FIG. 3 is a block diagram schematically showing a configuration of an inspection device for a collector head in the embodiments;

FIG. 4 is a schematic diagram of a procedure for rigidity measurement conducted by a measurer in the inspection device for a collector head in FIG. 3;

FIG. 5A is an example graph showing a rigidity distribution when a spring has a defect;

FIG. 5B is an example graph showing a rigidity distribution when arrangement of the contact strip has a defect;

FIG. 5C an example graph showing a rigidity distribution when a deflection plate has a defect; and

FIG. 6 is a flowchart of an inspection method of the collector head in the embodiments.

### DETAILED DESCRIPTION OF THE PREFERRED EMBODIMENTS

### 1. First Embodiment

### 1-1. Configuration

<Current Collector>

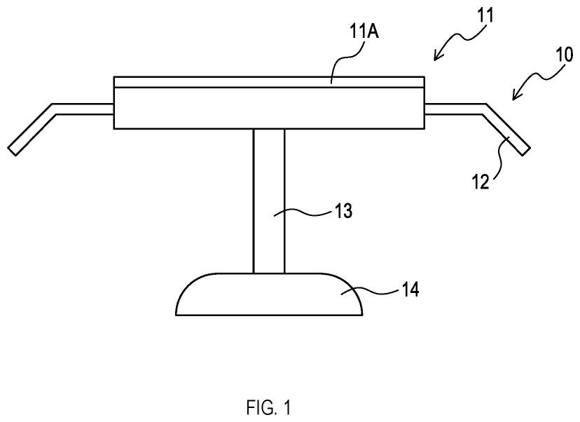

A current collector 10 of a railroad vehicle in FIG. 1 comprises a collector head 11, horns 12, a current collecting arm 13, and a base 14.

The collector head 11 has an overhead contact line contact assembly 11A which contacts an overhead contact line. The horns 12 prevent interruption of another overhead contact line along a direction different from a running direction of the railroad vehicle when the railroad vehicle passes a turnout. The current collecting arm 13 couples the collector head 11 and the base 14. The base 14 is attached on a roof of a body of the railroad vehicle.

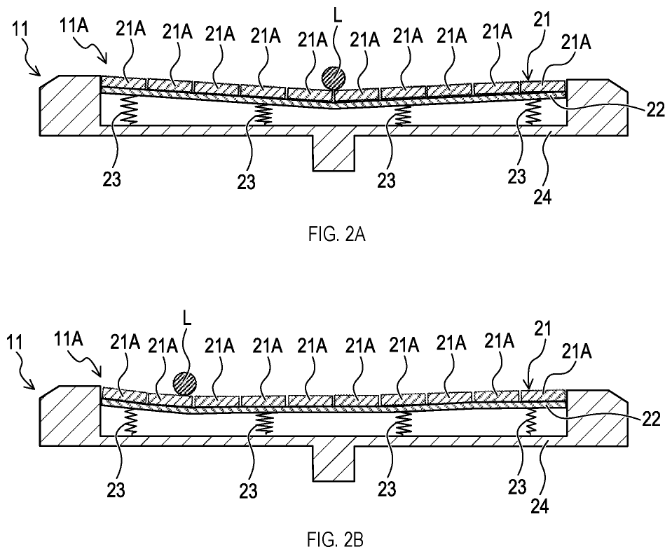

As shown in FIGS. 2A and 2B, the collector head 11 comprises a contact strip 21 to contact an overhead contact line L, a deflection plate 22 disposed at a lower surface of the contact strip 21, springs 23 disposed under the deflection plate 22, and a head body 24 that supports the springs 23. The overhead contact line contact assembly 11A of the collector head 11 comprises the contact strip 21, the deflection plate 22, and the springs 23.

The contact strip 21 comprises a electrically-conductive strip pieces 21A that are aligned in a series and in a longitudinal direction (a left-right direction in FIG. 2A) of a sleeper (namely, in a direction perpendicular to the vehicle's running direction). The strip pieces 21A are preferably made from materials such as metal and carbon. The strip pieces 21A and the head body 24 are electrically connected by conductive members (not shown).

In the present embodiment, all of the strip pieces 21A have identical shapes. However, some of the strip pieces 21A may have different shapes from the other strip pieces of the strip pieces 21A. The strip pieces 21A are preferably disposed spaced apart from one another in the longitudinal direction of the sleeper to allow the contact strip 21 to deflect and deform in the up-down direction. The strip pieces 21A are fixed on an upper surface of one deflection strip 22, which will be described below.

The deflection plate 22 is located between the strip pieces 21A and the springs 23. The deflection plate 22 is a band-like plate extending in the longitudinal direction of the sleeper and can deflect and deform in its thickness direction. The strip pieces 21A are fixed on an upper surface of the deflection plate 22. Furthermore, the springs 23 are coupled to a lower surface of the deflection plate 22.

When the deflection plate 22 serves as a conductive member for electrical connection between the strip pieces 21A and the head body 24, a material of the deflection plate 22 is selected from electrically-conductive ones, such as metal and carbon. However, in a case where the deflection plate 22 need not be conductive, the deflection plate 22 can be made from other materials that are non-conductive.

The springs 23 elastically support the contact strip 21 and the deflection plate 22. Each of the springs 23 is disposed such that its expansion/contraction direction (in other words, its axial direction) is parallel to the up-down direction. The springs 23 are coupled to the lower surface of the deflection plate 22 and a bottom surface of the head body 24.

The springs 23 are disposed spaced apart from one another in the longitudinal direction of the sleeper. In the present embodiment, the springs 23 are individually provided underneath some of the strip pieces 21A. However, the springs 23 may be each provided underneath a corresponding one of all the strip pieces 21A, or more than one springs 23 may be provided underneath one of the strip pieces 21A. Moreover, an elastic force (namely, a spring constant) of each of the springs 23 is appropriately determined based on a designed rigidity distribution of the collector head 11 in the longitudinal direction of the sleeper.

FIGS. 2A and 2B show examples of deformation of the overhead contact line contact assembly 11A in the collector head 11. When the overhead contact line L is positioned at the center of the collector head 11 along the longitudinal direction of the sleeper as shown in FIG. 2A, the contact strip 21 and the deflection plate 22 deflect to be recessed in a center area. In contrast, when the overhead contact line L is biased leftward along the longitudinal direction of sleeper as shown in FIG. 2B, the contact strip 21 and the deflection plate 22 are recessed in a left side area. That is, a deflection position of the overhead contact line contact assembly 11A varies depending on where the overhead contact line L is located.

The head body 24 retains the contact strip 21, the deflection plate 22 and the springs 23 (namely, the overhead contact line contact assembly 11A). The head body 24 has an opening in an upper surface, and the contact strip 21 is arranged in the opening. Furthermore, the head body 24 is coupled to the current collecting arm 13.

<Inspection Device for Collector Head>

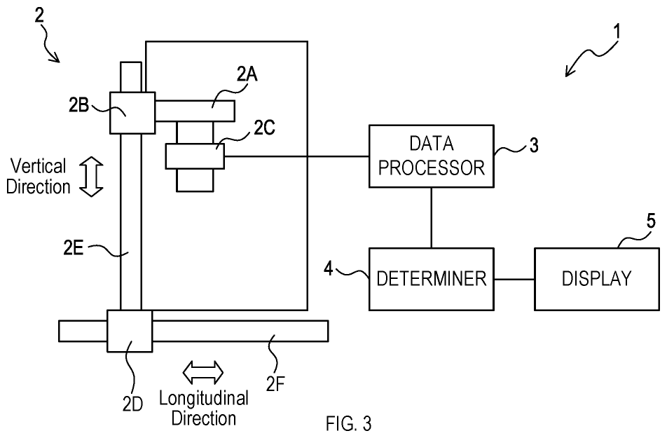

An inspection device for a collector head (hereinafter also simply referred to as “inspection device”) 1 as shown in FIG. 3 comprises a measurer 2, a data processor 3, a determiner 4, and a display 5. The data processor 3, the determiner 4, and the display 5 are configured, for example, by a computer having input/output units.

(Measurer)

The measurer 2 measures rigidity of the overhead contact line contact assembly 11A in the thickness direction of the contact strip 21 at multiple points in the longitudinal direction of the sleeper (namely, on an axis parallel to the juxtaposition direction of the strip pieces 21A).

Specifically, the measurer 2 comprises a measurement arm 2A, a displacement sensor 2B, a load sensor 2C, a position sensor 2D, a vertical arm 2E, and a horizontal arm 2F.

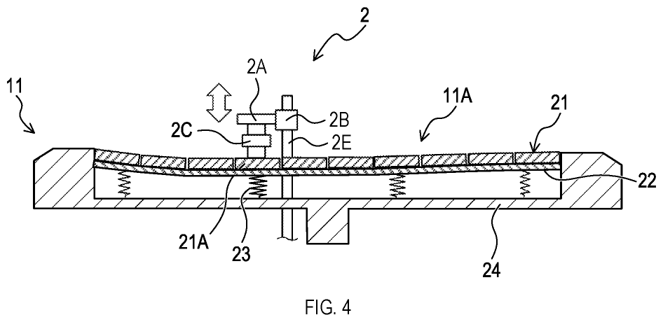

The measurement arm 2A is configured to be movable along both of the longitudinal direction of the sleeper and the up-down direction, and configured to apply a vertical load at an optional position of the contact strip 21 along the longitudinal direction of the sleeper as shown in FIG. 4.

The displacement sensor 2B is provided to the measurement arm 2A to measure a displacement of the contact strip 21 in the thickness direction (namely, the up-down direction) when a load is applied to the contact strip 21. The displacement sensor 2B accompanied by the measurement arm 2A is movable along the vertical arm 2E in the vertical direction. The load sensor 2C is provided to the measurement arm 2A to measure a load in the thickness direction (namely, a reaction force) applied to the contact strip 21 by the measurement arm 2A. The position sensor 2D detects a current position of the measurement arm 2A along the longitudinal direction of the sleeper. The position sensor 2D is movable along the horizontal arm 2F in the longitudinal direction of the sleeper.

(Data Processor)

The data processor 3 creates measurement data of rigidity distribution at multiple measuring points based on measurement results from the measurer 2.

Specifically, the data processor 3 calculates rigidity parameters by dividing a load measured by the load sensor 2C by a vertical displacement amount in the up-down direction based on the measurement value from the displacement sensor 2B at each position detected by the position sensor 2D.

(Determiner)

The determiner 4 determines whether an abnormality has occurred in the collector head 11 by comparing the measurement data of rigidity distribution, which is created by the data processor 3, with reference data of rigidity distribution, which is prepared in advance.

The reference data may be, for example, rigidity distribution data obtained by actually inspecting a good collector head or ideal rigidity distribution data obtained from analysis. The reference data is created in advance of inspection and stored in a storage of the inspection device 1 (not shown).

The determiner 4 determines that the collector head 11 has an abnormality, for example, when there is a measuring point at which the rigidity difference between the measurement data and the reference data exceeds a threshold, or, when a summed value of the rigidity differences at the respective measuring points exceeds the threshold.

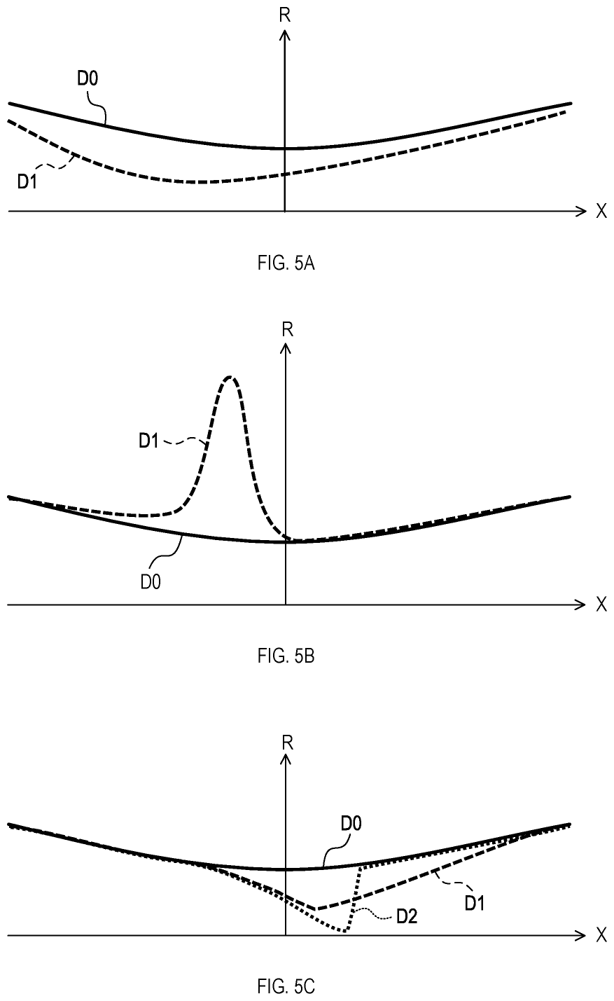

When the determiner 4 determines that the collector head 11 has an abnormality, the determiner 4 determines an abnormality occurring portion in the collector head 11 based on characteristics of the measurement data (namely, comparison results between the measurement data and the reference data). The abnormality occurring portion represents a part in which the abnormality occurs or an area of the part where the abnormality occurs. Graphs in FIGS. 5A, 5B, and 5C show examples of respective measurement data having different abnormality occurring portions.

In FIG. 5A, a rigidity R of first measurement data D1 as a whole is below the reference data DO and greatly decreases in a particular region along a longitudinal direction of sleeper X. Also, the rigidity R of the first measurement data D1 with respect to the longitudinal direction of sleeper X shows a gradual change.

In this case, it is assumed (probable) that one of the springs 23 has a defect (for example, abnormality in spring constant due to attachment of a wrong spring). This assumption is based on that the rigidity decreases gradually from the spring 23 as the center as the elastic force of the spring 23 becomes smaller. The measured rigidity may show a locally drastic change when the spring 23 has a defect; however, the change in rigidity may be partially absorbed (spread out) by deformation of the deflection strip 22, which is included in the collector head 11 in the present embodiment.

In FIG. 5B, the rigidity R of the first measurement data D1 is locally far above that of the reference data DO in a particular region along the longitudinal direction of the sleeper X. In other areas, the first measurement data D1 is approximately identical to the reference data DO.

In this case, it is assumed (probable) that there is a defect in interval between two or more adjacent strip pieces 21A. This assumption is based on that if there is no interval between the adjacent strip pieces 21A, then strip pieces 21A relating to such defect behave as one rigid body, resulting in an extremely high rigidity.

In FIG. 5C, the rigidity R of the first measurement data D1 is locally below that of the reference data DO in a particular region along the longitudinal direction of sleeper X. Also, the region in which the rigidity R of the first measurement data D1 is below that of the reference data DO extends sidewise, and the rigidity R of the first measurement data D1 changes in a relatively smooth manner.

In FIG. 5C, the rigidity R of the second measurement data D2 is locally below that of the reference data DO and is close to zero in a particular region along the longitudinal direction of sleeper X. The region in which the rigidity R of the second measurement data D2 is below that of the reference data DO is narrower than the region in which the rigidity R of the first measurement data D1 is below that of the reference data DO. Furthermore, the rigidity R of the second measurement data D2 changes more drastically than that of the first measurement data D1.

Based on each of the first measurement data D1 and the second measurement data D2, it is assumed that there is a local defect in the deflection plate 22. It is assumed from the first measurement data D1 that a plastic deformation has occurred to the deflection plate 22 because once the deflection plate 22 plastically deforms, the rigidity around the deformed portion deteriorates.

In contrast, it is assumed (probable) from the second measurement data D2 that a rupture has occurred to the deflection plate 22. Once the deflection plate 22 is ruptured, coupling between the adjacent strip pieces 21A in the longitudinal direction of the sleeper X is lost, causing a drastic change in the rigidity, and the constraint in the longitudinal direction of the sleeper is lost at a rupture point, resulting in an approximately zero rigidity.

The determiner 4 may be provided beforehand with a table, which is prepared based on the above-described actual examples, of correspondence between a tendency of rigidity difference between the measurement data and the reference data and each abnormality occurring portion, so that the determiner 4 can determine that there is an abnormality from the comparison results between the measurement data and the reference data.

(Display)

The display 5 displays determination results by the determiner 4. The determination results include, for example, existence or absence of an abnormality, an abnormality occurring portion (location, or identification of a specific part), and a type of the abnormality.

### 1-2. Effects

According to the above-detailed first embodiment, the following effects can be obtained.

(1a) The determiner 4 can determine whether the collector head 11 has a rigidity distribution required for improving contact stability with the overhead contact line. In other words, a defect in the collector head 11 can be determined from the viewpoint of current collection performance; thus, proper quality control of the collector head 11 can be achieved.

(1b) The rigidity of the overhead contact line contact assembly 11A at multiple measuring points can be easily and securely measured by using the displacement sensor 2B and the load sensor 2C provided to the measurement arm 2A.

(1c) The determiner 4 determines the abnormality occurring portion in the collector head 11 based on the comparison results between the measurement data and the reference data, thus facilitating identification of the cause of the defect in the collector head 11.

### 2. Second Embodiment

### 2-1. Configuration

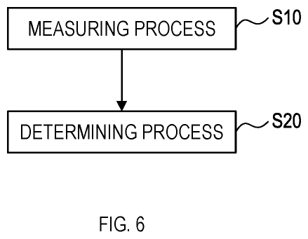

An inspection method of a collector head shown in FIG. 6 uses the inspection device for a collector head 1 shown in FIG. 3 to inspect the collector head 11 in FIG. 1. The inspection method of the collector head comprises a measuring process S10 and a determining process S20.

In the measuring process S10, rigidity of the overhead contact line contact assembly 11A in the thickness direction of the contact strip 21 is measured at multiple points on an axis parallel to the juxtaposition direction of the strip pieces 21A.

In the determining process S20, an abnormality occurred in the collector head 11 is determined by comparing measurement data of rigidity distribution at multiple points based on the measurement results in the measuring process S10 with reference data of rigidity distribution prepared beforehand.

This inspection method of a collector head does not necessarily use the inspection device for a collector head 1 shown in FIG. 3. In other words, either or both of the measuring process S10 and the determining process S20 may be manually conducted.

### 2-2. Effects

According to the above-detailed second embodiment, the following effects can be obtained:

(2a) The quality of the collector head 11 can be properly controlled since a defect in the collector head 11 can be determined from the viewpoint of current collection performance.

### 3. Other Embodiments

It is to be understood that although some embodiments of the present disclosure have been described above, the present disclosure is not limited to the aforementioned embodiments, but may be implemented in various forms.

(3a) The collector head to be inspected by the inspection device for a collector head 1 of the aforementioned embodiments need not necessarily have a deflection plate. In other words, the present disclosure is applicable to collector heads without deflection plates.

(3b) In the inspection device for a collector head 1 of the aforementioned embodiments, the measurer 2 may use apparatuses other than the displacement sensor 2B and the load sensor 2C for the purpose of measuring the rigidity of the overhead contact line contact assembly 11A.

(3c) In the inspection device for a collector head 1 of the aforementioned embodiments, the determiner 4 need not necessarily determine the abnormality occurring portion in the collector head 11. In other words, the determiner 4 may determine only whether there is an abnormality or not in the collector head 11.

(3d) A function performed by a single element in the aforementioned embodiments may be achieved by a plurality of elements, or a function performed by a plurality of elements may be achieved by a single element. Also, a part of a configuration in the aforementioned embodiments may be omitted. Further, at least a part of a configuration in one of the aforementioned embodiments may be added to, or may be replaced with, a configuration in another one of the aforementioned embodiments. Any form included in the technical idea defined by the language of the appended claims may be an embodiment of the present disclosure.

What is claimed is:

1. An inspection device for a collector head, comprising:
wherein the collector head comprises an overhead contact line contact assembly,
wherein the overhead contact line contact assembly includes a contact strip and
springs elastically supporting the contact strip,
wherein the contact strip includes electrically-conductive strip pieces aligned in
a series in a longitudinal direction, the inspection device comprising:
a measurer configured to measure rigidity of the overhead contact line contact assembly in a thickness direction of the contact strip at multiple points on an axis parallel to the juxtaposition direction of the strip pieces; and
a determiner configured to determine whether an abnormality has occurred in the collector head by comparison of measurement data of rigidity distribution at the multiple points based on measurement results from the measurer with reference data of rigidity distribution prepared beforehand.

2. The inspection device for a collector head according to claim 1,
wherein the collector head further comprises a deflection plate that is located between the strip pieces and the springs, and is deformable in a thickness direction of the deflection plate.

3. The inspection device for a collector head according to claim 1,
wherein the measurer comprises:
a displacement sensor configured to measure a displacement of the contact strip in its thickness direction of the contact strip; and
a load sensor configured to measure a load applied on the contact strip in its thickness direction of the contact strip.

4. The inspection device for a collector head according to claim 1,
wherein the determiner is configured to determine an abnormality occurring portion in the collector head based on results of a comparison between measurement data and reference data.

5. An inspection method of a collector head, comprising processes of:
wherein the collector head comprises an overhead contact line contact assembly,
wherein the overhead contact line contact assembly includes a contact strip and
springs elastically supporting the contact strip,
wherein the contact strip includes electrically-conductive strip pieces aligned in a series in a longitudinal direction, the inspection method comprising processes of:
measuring rigidity of the overhead contact line contact assembly in a thickness direction of the contact strip at multiple points on an axis parallel to the juxtaposition direction of the strip pieces; and
determining whether an abnormality has occurred in the collector head by comparison of measurement data of rigidity distribution at the multiple points based on measurement results obtained in the measuring process with reference data of rigidity distribution prepared beforehand.
